(19) United States
(12) Patent Application Publication
(10) Pub. No.: US 2025/0314853 A1
(43) Pub. Date: Oct. 9, 2025

(54) OPTICAL SYSTEM AND PROJECTION EXPOSURE APPARATUS

(71) Applicant: Carl Zeiss SMT GmbH, Oberkochen (DE)

(72) Inventor: Maximilian SCHWENK, Zoeschingen (DE)

(21) Appl. No.: 19/241,680

(22) Filed: Jun. 18, 2025

Related U.S. Application Data
(63) Continuation of application No. PCT/EP2023/082725, filed on Nov. 22, 2023.

(30) Foreign Application Priority Data
Dec. 21, 2022 (DE) 10 2022 214 184.9

(51) Int. Cl. G02B 7/182; G03F 7/00

(52) U.S. Cl. CPC G02B 7/182; G03F 7/70233; G03F 7/70825

(57) ABSTRACT

An optical system for a projection exposure apparatus, comprising a first component, a second component, and a fastening device used to attach the second component to the first component. The fastening device has a decoupling bushing for mechanically decoupling the second component from the first component. The decoupling bushing has a decoupling groove reducing the rigidity of the decoupling bushing.

### CROSS-REFERENCE TO RELATED APPLICATIONS

The present application is a continuation of, and claims benefit under 35 USC 120 to, international application No. PCT/EP2023/082725, filed Nov. 22, 2023, which claims benefit under 35 USC 119 of German Application No. 10 2022 214 184.9, filed Dec. 21, 2022. The entire disclosure of each of these applications is incorporated by reference herein.

### FIELD

The present disclosure relates to an optical system and to a projection exposure apparatus comprising such an optical system.

### BACKGROUND

Microlithography is used for producing microstructured devices, such as for example integrated circuits. The microlithography process is performed using a lithography apparatus, which comprises an illumination system and a projection system. The image of a mask (reticle) illuminated via the illumination system is projected via the projection system onto a substrate, for example a silicon wafer, which is coated with a light-sensitive layer (photoresist) and arranged in the image plane of the projection system, in order to transfer the mask structure to the light-sensitive coating of the substrate.

Driven by the desire for ever smaller structures in the production of integrated circuits, EUV lithography apparatuses that use light with a wavelength in the range of 0.1 nanometer (nm) to 30 nm, for example 13.5 nm, and DUV lithography apparatuses that use light with a wavelength in the range of 30 nm to 250 nm are currently under development. However, lithography apparatuses with larger wavelengths, for example at 365 nm, are also possible. In the case of such EUV lithography apparatuses, because of the high absorption of light at this wavelength by most materials, reflective optics units, which is to say mirrors, typically are used instead of-as previously-refractive optics units, which is to say lens elements.

A projection system, as mentioned above, can have a sensor frame on which optical elements in the form of measurement targets are mounted, which are measured, for example, using an interferometer. The optical elements may be mounted on the sensor frame and the interferometer may be mounted on another component part. For mounting such an optical element on the sensor frame, a fastening device with a bushing adhesively bonded into the optical element can be used.

This fastening device can have spherical-cap-shaped spacers for compensating for angular errors between the optical element and the sensor frame. The bushing adhesively bonded into the optical element can have a contact surface which is likewise shaped like a spherical cap and on which one of the spacers abuts. Due to unfavorable friction conditions or due to deviations in shape caused by production which are such that lever ratios change unfavorably, it may be the case that the spacers do not slide into their optimal position, i.e. are not positioned optimally. Due to the resulting misalignment between the optical element and the sensor frame, a torque can be generated which can lead to unwanted deformation of the optical element.

### SUMMARY

The present disclosure seeks to provide an improved optical system.

Accordingly, an optical system for a projection exposure apparatus is proposed. The optical system comprises a first component, a second component, and a fastening device by which the second component is attached to the first component, wherein the fastening device has a decoupling bushing for mechanically decoupling the second component from the first component, and wherein the decoupling bushing has a decoupling groove reducing the rigidity of the decoupling bushing.

Because the decoupling bushing has the decoupling groove, it is possible to decouple the second component mechanically from the first component in such a way that no parasitic forces or torques which could deform the second component in an undesirable manner are transferred to the second component.

The optical system can be a projection optics unit or a part of such a projection optics unit of a projection exposure apparatus. However, the optical system can also be an illumination system or a part of such an illumination system of a projection exposure apparatus. The first component can be a sensor frame and can therefore also be referred to in this way. That is to say for example that the terms “first component” and “sensor frame” can be used interchangeably as desired. However, the first component can also be any other support structure supporting the second component. Exactly one decoupling groove may be provided. It is also possible for more, for example two, decoupling grooves to be provided.

The second component can be an optical element and can therefore also be referred to in this way. Accordingly, the terms “second component” and “optical element” can be used interchangeably as desired. For example, the second component is a measurement target. The second component is made, for example, of glass ceramic. The second component can have an optically effective surface. The optically effective surface may be a mirror surface. The optically effective surface can be configured to reflect light, such as a laser beam. The optical system may have an interferometer, which interacts with the optically effective surface of the second component.

A coordinate system having a first spatial direction or x-direction, a second spatial direction or y-direction, and a third spatial direction or z-direction is assigned to the optical system. The z-direction corresponds to or is parallel to an axis of symmetry or central axis of the fastening device or to the decoupling bushing. The x-direction and the y-direction are each perpendicular to the central axis and perpendicular to each other. An “angular error” is therefore understood to mean herein a tilt of the second component relative to the first component about the x-direction and/or the y-direction.

The second component has six degrees of freedom, namely three translational degrees of freedom along the x-direction, the y-direction, and the z-direction, and three rotational degrees of freedom about the x-direction, the y-direction and the z-direction. This means that a position and an orientation of the second component can be determined or described using the six degrees of freedom.

The “position” of the second component is understood to mean in particular its coordinates in relation to the x-direction, the y-direction, and the z-direction. In particular, the “orientation” of the second component is understood to mean its tilt with respect to the three directions. This makes up the six degrees of freedom for the position and orientation of the second component. A “pose” of the second component comprises both its position and its orientation. The term “pose” is accordingly replaceable by the wording “position and orientation”, and vice versa. For example, the pose of the second component can be detected using the interferometer.

The fastening device connects the second component to the first component. For example, the first component carries the second component. The fastening device can be constructed to be rotationally symmetric to its central axis. The fastening device can comprise a first sleeve and a second sleeve, which can be mounted at a perforation in the first component. The first sleeve and the second sleeve can be supported on the first component such that the first component is clamped between the first sleeve and the second sleeve. The first sleeve and the second sleeve may be screwed together.

Furthermore, the fastening device can comprise a threaded pin, which is screwed into the first sleeve. The threaded pin can pass through the decoupling bushing. The second sleeve can have a spherical-cap-shaped contact surface, on which a spherical-cap-shaped first contact surface of a first spherical cap element abuts. A “spherical cap” herein is understood to be a section of a sphere.

The first spherical cap element can have, in addition to the first contact surface, a flat second contact surface facing away from the first contact surface. The second contact surface can face a flat first contact surface of the decoupling bushing. Between the second contact surface of the first spherical cap element and the first contact surface of the decoupling bushing, a spacer in the form of a washer may be provided. A plurality of spacers may also be provided. The spacers are a way to maintain a distance. A plurality of different spacers may be disposed between the first spherical-cap element and the first contact surface of the decoupling bushing. For example, so-called coarse spacers and fine spacers may be provided. The first contact surface of the decoupling bushing can be a circular ring, which lies as far outside as possible with respect to a radial direction of the decoupling bushing. This can create a large lever arm, resulting in larger torques that allow for improved positioning. This can help make it easier to overcome frictional forces.

The threaded pin can pass through the first spherical cap element and the spacer. The decoupling bushing can be arranged between the first spherical cap element or the spacer and a second spherical cap element. The decoupling bushing can have a second contact surface facing away from the first contact surface, which second contact surface is shaped in the form of a spherical cap. The second spherical cap element can abut, with a first spherical-cap-shaped contact surface, the second contact surface of the decoupling bushing. The second spherical cap element can have a flat second contact surface facing away from the first contact surface. A nut screwed onto the threaded pin can abut the second contact surface. The nut can be used to clamp the two spherical cap elements, the decoupling bushing, the spacer(s), and the sleeves together. Here, torque-free screwing can be implemented. The threaded pin can be stretched in the process.

For example, the second component has a perforation in which the decoupling bushing is accommodated at least in sections. The decoupling bushing can be adhesively bonded into the perforation in particular. The decoupling bushing can be made of a different material than the second component. For example, the decoupling bushing is made of an iron-nickel alloy.

In particular, the decoupling bushing “mechanically decoupling” the first component and the second component from each other is understood herein to mean that the decoupling bushing prevents or at least reduces the transfer of forces and/or torques from the first component to the second component and vice versa. This can help reliably prevent unwanted deformation of the second component.

The fact that the decoupling groove “reduces” the rigidity of the decoupling bushing is herein understood to mean in particular that the decoupling bushing has a lower rigidity due to the decoupling groove compared with a solid decoupling bushing. The “rigidity” is understood herein to mean the resistance of a body, in particular the decoupling bushing, to an elastic deformation impressed thereon by an external load and conveys the relationship between the load on the body and its deformation. The rigidity is generally determined by the material of the body and its geometry. This means that the rigidity of the decoupling bushing can be varied over a wide range by a suitable selection of the material used and the geometry of the decoupling groove.

The compensating bushing can also compensate or compensate for angular errors between the first component and the second component at least to a certain degree. This means that the decoupling bushing “compensates” for angular errors between the first component and the second component, in particular, that the decoupling bushing can deform elastically due to its rigidity reduced by the decoupling groove, in such a way that the angular errors within the decoupling bushing itself are compensated. This can be accomplished, for example, by the fact that different sections of the decoupling bushing, for example a connection section and a fastening section, can move relative to one another. The second component can therefore be moved into a target pose without forces being introduced into the second component via the decoupling bushing. This can help reliably prevent unwanted deformation of the second component.

According to one embodiment, the decoupling groove extends in the shape of a ring around a central axis of the decoupling bushing.

In particular, this means that the decoupling groove is a ring groove. The terms “decoupling groove” and “ring groove” can therefore be used interchangeably as desired. The central axis of the decoupling bushing may coincide with the central axis of the fastening device. The decoupling bushing can be rotationally symmetric to its central axis. The decoupling groove can have a rectangular cross section. However, the decoupling groove may also have a round or rounded groove base. The decoupling groove extends along the central axis of the decoupling bushing. Exactly one decoupling groove may be provided. However, a plurality of decoupling grooves may also be introduced into the decoupling bushing. For example, a first decoupling groove and a second decoupling groove differing from the first decoupling groove are provided.

According to an embodiment, the decoupling bushing has a first decoupling groove and a second decoupling groove, wherein the first decoupling groove extends from a first end face of the decoupling bushing in the direction of a second end face of the decoupling bushing, and wherein the second decoupling groove extends from the second end face in the direction of the first end face.

The end faces are positioned at the decoupling bushing to face away from one another. The decoupling grooves therefore can run from different end faces of the decoupling bushing into the latter. The two decoupling grooves can be separated from each other by a bridge that rotationally symmetrically runs around the axis of symmetry. This means for example that the first decoupling groove and the second decoupling groove are not connected to each other. The first decoupling groove only partially breaks through the decoupling bushing and therefore not completely. The same applies to the second decoupling groove. The decoupling bushing is for example cylindrical and has a cylindrical outer surface. The first end face and the second end face are provided on the front side of the decoupling bushing. The first decoupling groove breaks through the first end face, but not the second end face. Accordingly, the second decoupling groove breaks through the second end face, but not the first end face.

According to an embodiment, the first decoupling groove is arranged, viewed along a radial direction of the decoupling bushing, within the second decoupling groove.

The radial direction is oriented perpendicularly to the central axis of the decoupling bushing and away from the latter. Thus, the first decoupling groove is placed within the second decoupling groove when viewed along the radial direction, and the second decoupling groove is positioned outside the first decoupling groove when viewed along the radial direction. The first decoupling groove and the second decoupling groove are thus interleaved.

According to an embodiment, the first decoupling groove and the second decoupling groove overlap when viewed along the central axis.

This means in particular that the first decoupling groove covers the second decoupling groove when viewed along the radial direction, and vice versa. In particular, the first decoupling groove and the second decoupling groove are thus, when viewed along the central axis, at least in sections placed side by side, wherein the first decoupling groove and the second decoupling groove are separated from each other by the aforementioned bridge.

According to an embodiment, the decoupling bushing has a connection section connected to the first component and a fastening section connected to the second component, wherein the decoupling groove is arranged between the connection section and the fastening section.

In particular, the decoupling groove mechanically decouples the connection section from the fastening section. “Mechanical decoupling” is herein understood to mean in particular that no or only minimal forces can be transferred from the connection section to the fastening section and vice versa. The connection section is connected, for example screwed, to the first component via the two spherical cap elements, the spacer, the two sleeves, the threaded pin, and the nut. The fastening section can be adhesively bonded to the second component. For example, the fastening section is adhesively bonded into the perforation in the second component. The fastening section and the connection section are tubular or hollow-cylindrical in each case. The decoupling groove is provided between the connection section and the fastening section. The connection section can have a central perforation, such as a drilled hole, through which the threaded pin passes without contact.

According to an embodiment, the connection section and the fastening section are connected to each other only via a bridge acting as a flexure.

This means in particular that the decoupling groove or the decoupling grooves separate the connection section from the fastening section. A connection between the connection section and the fastening section is realized using only the bridge. The bridge is elastically, for example spring-elastically, deformable. “Elastic deformation” is understood to mean herein in particular that the bridge can be moved from a non-deformed state to a deformed state by applying a force or a torque. If this force or this torque no longer acts on the bridge, the latter is brought back automatically from the deformed state to the non-deformed state. In the present case, a “flexure” is understood to mean in particular a region of a component part which, by bending, enables a relative movement between two rigid body regions. In the present case, the fastening section and the connection section act as rigid body regions, between which the bridge is provided as an elastically deformable flexure.

According to an embodiment, the bridge is sleeve-shaped.

The bridge can also be called tubular or hollow-cylindrical. The bridge can run completely around the central axis of the decoupling bushing. For example, the bridge also runs completely around the connection section. The bridge is arranged along the radial direction, for example between the connection section and the fastening section.

According to an embodiment, the bridge has slits that break through the bridge.

The slits can can run along the central axis of the decoupling bushing. There may be any desired number of slits. The slits can be distributed evenly around the central axis of the decoupling bushing. The slits can be used, for example, to further reduce the rigidity of the bridge. Thus, the rigidity of the bridge can be varied, for example reduced, with the aid of the slits. The slits can have a rectangular geometry.

According to an embodiment, the connection section has a flat first contact surface and a spherical-cap-shaped second contact surface facing away from the first contact surface.

As mentioned above, the spacer or the first spherical cap element can abut the first contact surface. The second spherical cap element can abut the second contact surface.

According to an embodiment, the decoupling bushing has a first centering ring and a second centering ring for centering the decoupling bushing in a perforation provided in the second component.

The first centering ring and the second centering ring can extend, when viewed along the radial direction, radially from the aforementioned outer surface of the decoupling bushing or the fastening section. The two centering rings can be used to center the decoupling bushing in the perforation in the second component.

According to an embodiment, the decoupling bushing has a first fastening ring and a second fastening ring for attaching the decoupling bushing to the perforation, wherein the first fastening ring and the second fastening ring are arranged between the first centering ring and the second centering ring.

For example, the first fastening ring and the second fastening ring are arranged, viewed along the central axis of the compensating bushing, between the first centering ring and the second centering ring. Using the first fastening ring and the second fastening ring, the decoupling bushing can be bonded to the second component. For this purpose, an adhesive layer can be provided in each case between the two fastening rings and the second component. The fastening rings can be adhesively bonded into the perforation in the second component. For example, the decoupling bushing or the fastening rings are adhesively bonded radially to the second component. Alternatively, axial adhesive bonding can also be realized.

According to an embodiment, the decoupling bushing has exactly one fastening ring for attaching the decoupling bushing to the perforation, wherein the fastening ring is arranged between the first centering ring and the second centering ring.

For example, the fastening ring is arranged, when viewed along the central axis of the decoupling bushing, centrally between the first centering ring and the second centering ring. This can be a desirable arrangement. The central arrangement of the fastening ring further reduces the introduction of forces and/or torques to the second component. This is the result of a reduced lever arm.

According to an embodiment, the decoupling bushing is a component part formed in one piece, in particular materially in one piece.

“In one piece” or “in one part” herein means in particular that the decoupling bushing is not composed of different subordinate component parts, but rather that the connection section, the fastening section and the bridge form a common component part, namely the decoupling bushing. The term “materially in one piece” means that the decoupling bushing is made of the same material throughout. As mentioned above, for example, an iron-nickel alloy can be used for the decoupling bushing.

Further, a projection exposure apparatus having such an optical system is proposed.

The optical system can be a projection optics unit of a projection exposure apparatus. However, the optical system may also be an illumination system. A projection exposure apparatus may be an EUV lithography apparatus. EUV stands for “extreme ultraviolet” and refers to a wavelength of the operating light of between 0.1 nm and 30 nm. The projection exposure apparatus can also be a DUV lithography apparatus. DUV stands for “deep ultraviolet” and refers to a wavelength of the operating light of between 30 nm and 250 nm. However, lithography apparatuses with larger wavelengths, for example at 365 nm, are also possible.

“A” or “an” in the present case should not necessarily be understood as a restriction to exactly one element. Rather, there may also be multiple elements, for example two, three or more. Any other numeral used here should also not be understood as a restriction to exactly the stated number of elements. Rather, numerical deviations upward and downward are possible, unless indicated otherwise.

The embodiments and features described for the optical system apply correspondingly to the proposed projection exposure apparatus, and vice versa.

Further possible implementations of the disclosure also encompass not explicitly mentioned combinations of features or embodiments that are described above or hereinafter with respect to the exemplary embodiments. A person skilled in the art will also add individual aspects as improvements or supplementations to the respective basic form of the disclosure.

Further configurations and aspects of the disclosure are the subject matter of the dependent claims and of the exemplary embodiments of the disclosure described below. The disclosure is explained in greater detail hereinafter on the basis of certain embodiments with reference to the accompanying figures.

### BRIEF DESCRIPTION OF THE DRAWINGS

FIG. 1 shows a schematic meridional section of a projection exposure apparatus for EUV projection lithography.

FIG. 2 shows a schematic sectional view of an embodiment of an optical system for the projection exposure apparatus according to FIG. 1.

FIG. 3 shows a schematic sectional view of an embodiment of a decoupling bushing for the optical system according to FIG. 2.

FIG. 4 shows a schematic plan view of the decoupling bushing in accordance with FIG. 3.

FIG. 5 shows a schematic bottom view of the decoupling bushing according to FIG. 3.

FIG. 6 shows a schematic sectional view of a further embodiment of a decoupling bushing for the optical system according to FIG. 2.

FIG. 7 shows a schematic sectional view of a further embodiment of a decoupling bushing for the optical system according to FIG. 2.

FIG. 8 shows a schematic sectional view of a further embodiment of a decoupling bushing

### DETAILED DESCRIPTION

In the figures, identical or functionally identical elements have been provided with the same reference signs, unless indicated otherwise. It should also be noted that the illustrations in the figures are not necessarily to scale.

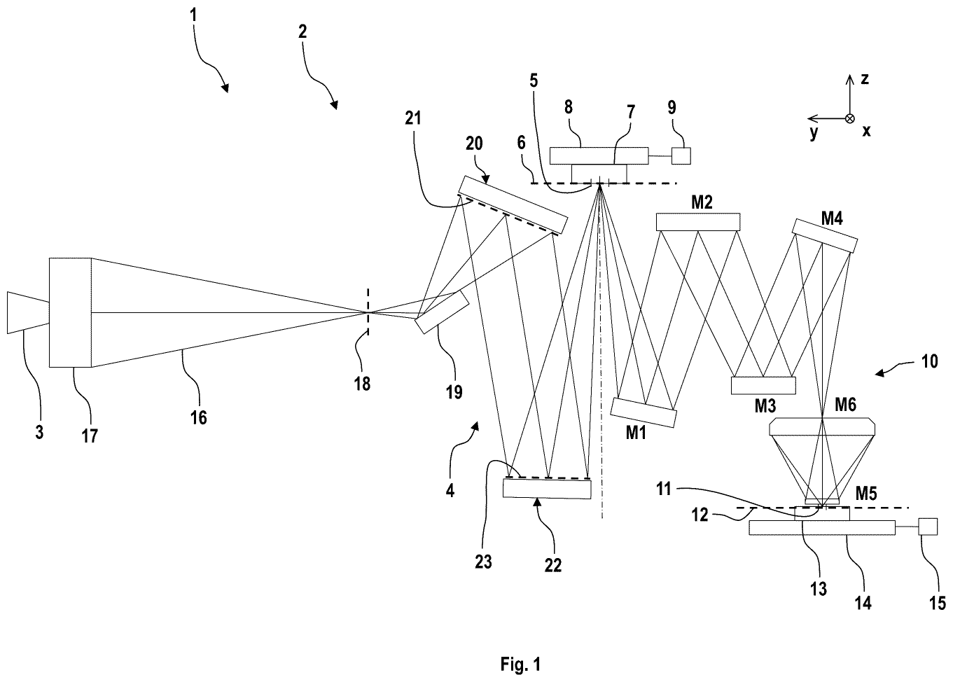

FIG. 1 shows an embodiment of a projection exposure apparatus 1 (lithography apparatus), for example an EUV lithography apparatus. In addition to a light source or radiation source 3, an embodiment of an illumination system 2 of the projection exposure apparatus 1 has an illumination optics unit 4 for illuminating an object field 5 in an object plane 6. In an alternative embodiment, the light source 3 may also be provided as a module separate from the rest of the illumination system 2. In this case, the illumination system 2 does not comprise the light source 3.

A reticle 7 arranged in the object field 5 is exposed. The reticle 7 is held by a reticle holder 8. The reticle holder 8 is displaceable by way of a reticle displacement drive 9, for example in a scanning direction.

FIG. 1 shows, for explanation purposes, a Cartesian coordinate system with an x-direction x, a y-direction y, and a z-direction z. The x-direction x runs perpendicularly into the plane of the drawing. The y-direction y runs horizontally, and the z-direction z runs vertically. The scanning direction runs along the y-direction y in FIG. 1. The z-direction z runs perpendicularly to the object plane 6.

The projection exposure apparatus 1 comprises a projection optics unit 10. The projection optics unit 10 serves for imaging the object field 5 into an image field 11 in an image plane 12. The image plane 12 extends parallel to the object plane 6. In an alternative, an angle that differs from 0° is also possible between the object plane 6 and the image plane 12.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable by way of a wafer displacement drive 15, for example in the y-direction y. The displacement firstly of the reticle 7 by way of the reticle displacement drive 9 and secondly of the wafer 13 by way of the wafer displacement drive 15 may be implemented so as to be mutually synchronized.

The light source 3 is an EUV radiation source. The light source 3 emits EUV radiation 16, which is also referred to below as used radiation, illumination radiation or illumination light. The used radiation 16 has for example a wavelength in the range of between 5 nm and 30 nm. The light source 3 can be a plasma source, for example an LPP (short for: laser produced plasma) source or a DPP (short for: gas-discharge produced plasma) source. It can also be a synchrotron-based radiation source. The light source 3 can be an FEL (short for: free-electron laser).

The illumination radiation 16 emanating from the light source 3 is focused by a collector 17. The collector 17 can be a collector having one or more ellipsoidal and/or hyperboloidal reflection surfaces. The at least one reflection surface of the collector 17 can be impinged upon by the illumination radiation 16 with grazing incidence (abbreviated as: GI), which is to say with angles of incidence greater than 45°, or with normal incidence (abbreviated as: NI), which is to say with angles of incidence less than 45°. The collector 17 can be structured and/or coated firstly to optimize its reflectivity for the used radiation and secondly to suppress extraneous light.

Downstream of the collector 17, the illumination radiation 16 propagates through an intermediate focus in an intermediate focal plane 18. The intermediate focal plane 18 can represent a separation between a radiation source module, comprising the light source 3 and the collector 17, and the illumination optics unit 4.

The illumination optics unit 4 comprises a deflection mirror 19 and, disposed downstream thereof in the beam path, a first facet mirror 20. The deflection mirror 19 may be a plane deflection mirror or, in an alternative to that, a mirror with a beam-influencing effect going beyond the pure deflection effect. Alternatively or additionally, the deflection mirror 19 may be in the form of a spectral filter, which separates a used light wavelength of the illumination radiation 16 from extraneous light of a different wavelength. Should the first facet mirror 20 be arranged in a plane of the illumination optics unit 4 which is optically conjugate to the object plane 6 as a field plane, this facet mirror is also referred to as a field facet mirror. The first facet mirror 20 comprises a multiplicity of individual first facets 21, which can also be referred to as field facets. Only some of these first facets 21 are illustrated in FIG. 1 by way of example.

The first facets 21 may take the form of macroscopic facets, for example as rectangular facets or as facets with an arc-shaped or part-circular edge contour. The first facets 21 may take the form of plane facets or, in an alternative to that, convexly or concavely curved facets.

As is known for example from DE 10 2008 009 600 A1, the first facets 21 themselves may each also be composed of a multiplicity of individual mirrors, for example a multiplicity of micromirrors. The first facet mirror 20 may take the form of a microelectromechanical system (MEMS system) for example. For details, reference is made to DE 10 2008 009 600 A1.

The illumination radiation 16 propagates horizontally, i.e. in the y-direction y, between the collector 17 and the deflection mirror 19.

In the beam path of the illumination optics unit 4, a second facet mirror 22 is disposed downstream of the first facet mirror 20. Should the second facet mirror 22 be arranged in a pupil plane of the illumination optics unit 4, this facet mirror is also referred to as a pupil facet mirror. The second facet mirror 22 may also be spaced apart from a pupil plane of the illumination optics unit 4. In this case, the combination of the first facet mirror 20 and the second facet mirror 22 is also referred to as a specular reflector. Specular reflectors are known from US 2006/0132747 A1, EP 1 614 008 B1, and U.S. Pat. No. 6,573,978.

The second facet mirror 22 comprises a plurality of second facets 23. In the case of a pupil facet mirror, the second facets 23 are also referred to as pupil facets.

The second facets 23 can likewise be macroscopic facets, which can for example have a round, rectangular or hexagonal boundary, or can alternatively be facets composed of micromirrors. For details in this regard, reference is likewise made to DE 10 2008 009 600 A1.

The second facets 23 may have plane or, alternatively, convexly or concavely curved reflection surfaces.

The illumination optics unit 4 thus forms a doubly faceted system. This fundamental principle is also referred to as a fly's eye integrator.

It can be desirable to arrange the second facet mirror 22 not exactly in a plane that is optically conjugate to a pupil plane of the projection optics unit 10. For example, the second facet mirror 22 may be arranged so as to be tilted in relation to a pupil plane of the projection optics unit 10, as described for example in DE 10 2017 220 586 A1.

The second facet mirror 22 is used to image the individual first facets 21 into the object field 5. The second facet mirror 22 is the last beam-shaping mirror or actually the last mirror for the illumination radiation 16 in the beam path upstream of the object field 5.

In a further embodiment (not illustrated) of the illumination optics unit 4, a transfer optics unit contributing for example to the imaging of the first facets 21 into the object field 5 may be arranged in the beam path between the second facet mirror 22 and the object field 5. The transfer optics unit may have exactly one mirror or, in an alternative to that, two or more mirrors, which are arranged one behind another in the beam path of the illumination optics unit 4. The transfer optics unit may for example comprise one or two normal-incidence mirrors (NI mirrors) and/or one or two grazing-incidence mirrors (GI mirrors).

In the embodiment shown in FIG. 1, the illumination optics unit 4 has exactly three mirrors downstream of the collector 17, specifically the deflection mirror 19, the first facet mirror 20, and the second facet mirror 22.

In a further embodiment of the illumination optics unit 4, the deflection mirror 19 may also be omitted, and so the illumination optics unit 4 may then have exactly two mirrors downstream of the collector 17, specifically the first facet mirror 20 and the second facet mirror 22.

The imaging of the first facets 21 into the object plane 6 via the second facets 23 or using the second facets 23 and a transfer optics unit is, as a rule, only approximate imaging.

The projection optics unit 10 comprises a plurality of mirrors Mi, which are consecutively numbered in accordance with their arrangement in the beam path of the projection exposure apparatus 1.

In the example illustrated in FIG. 1, the projection optics unit 10 comprises six mirrors M1 to M6. Alternatives with four, eight, ten, twelve or any other number of mirrors Mi are likewise possible. The projection optics unit 10 is a doubly obscured optics unit. The penultimate mirror M5 and the last mirror M6 each have a passage opening for the illumination radiation 16. The projection optics unit 10 has an image-side numerical aperture which is greater than 0.5 and which may also be greater than 0.6 and which, for example, may be 0.7 or 0.75. However, the numerical aperture can also be less than 0.5.

Reflection surfaces of the mirrors Mi may be in the form of free-form surfaces without an axis of rotational symmetry. Alternatively, the reflection surfaces of the mirrors Mi can be designed as aspherical surfaces with exactly one axis of rotational symmetry of the reflection surface shape. Just like the mirrors of the illumination optics unit 4, the mirrors Mi may have highly reflective coatings for the illumination radiation 16. These coatings may be designed as multilayer coatings, for example with alternating layers of molybdenum and silicon.

The projection optics unit 10 has a large object-image offset in the y-direction y between a y-coordinate of a center of the object field 5 and a y-coordinate of the center of the image field 11. This object-image offset in the y-direction y can be of approximately the same magnitude as a z-distance between the object plane 6 and the image plane 12.

For example, the projection optics unit 10 may have an anamorphic design. It has for example different imaging scales βx, βy in the x-and y-directions x, y. The two imaging scales βx, βy of the projection optics unit 10 can be (βx, βy)=(+/−0.25, +/−0.125). A positive imaging scale β means imaging without image inversion. A negative sign for the imaging scale β means imaging with image inversion.

The projection optics unit 10 consequently leads to a reduction in size with a ratio of 4:1 in the x-direction x, i.e. in a direction perpendicular to the scanning direction.

The projection optics unit 10 leads to a reduction in size of 8:1 in the y-direction y, i.e. in the scanning direction.

Other imaging scales are likewise possible. Imaging scales with the same sign and the same absolute value in the x-direction x and y-direction y are also possible, for example with absolute values of 0.125 or of 0.25.

The number of intermediate image planes in the x-direction x and in the y-direction y in the beam path between the object field 5 and the image field 11 can be the same or can differ, depending on the embodiment of the projection optics unit 10. Examples of projection optics units with different numbers of such intermediate images in the x-direction x and y-direction y are known from US 2018/0074303 A1.

In each case, one of the second facets 23 is assigned to exactly one of the first facets 21 for forming in each case an illumination channel for illuminating the object field 5. This may yield in particular illumination according to the Köhler principle. The far field is decomposed into a multiplicity of object fields 5 with the aid of the first facets 21. The first facets 21 create a plurality of images of the intermediate focus on the second facets 23 respectively assigned to them.

The first facets 21 are each imaged onto the reticle 7 by an assigned second facet 23 and overlaid over one another for the purpose of illuminating the object field 5. The illumination of the object field 5 is for example as homogeneous as possible. It can have a uniformity error of less than 2%. Field uniformity may be achieved by overlaying different illumination channels.

The illumination of the entrance pupil of the projection optics unit 10 can be defined geometrically by an arrangement of the second facets 23. The intensity distribution in the entrance pupil of the projection optics unit 10 can be set by selecting the illumination channels, for example the subset of the second facets 23, which guide light. This intensity distribution is also referred to as illumination setting or illumination pupil filling.

A likewise preferred pupil uniformity in the region of sections of an illumination pupil of the illumination optics unit 4 which are illuminated in a defined manner may be achieved by a redistribution of the illumination channels.

Further aspects and details of the illumination of the object field 5 and for example of the entrance pupil of the projection optics unit 10 are described below.

The projection optics unit 10 may have for example a homocentric entrance pupil. The latter may be accessible. It may also be inaccessible.

The entrance pupil of the projection optics unit 10 regularly cannot be exactly illuminated with the second facet mirror 22. In the case of an imaging process of the projection optics unit 10 which telecentrically images the center of the second facet mirror 22 onto the wafer 13, the aperture rays often do not intersect in a single point. However, it is possible to find an area in which the spacing of the aperture rays that is determined in pairs becomes minimal. This area represents the entrance pupil or an area conjugate thereto in real space. For example, this area exhibits a finite curvature.

It may be the case that the projection optics unit 10 has different poses of the entrance pupil for the tangential beam path and for the sagittal beam path. In this case, an imaging element, for example an optical structural element of the transfer optics unit, should be provided between the second facet mirror 22 and the reticle 7. With this optical element, the different poses of the tangential entrance pupil and the sagittal entrance pupil may be taken into account.

In the arrangement of the components of the illumination optics unit 4 illustrated in FIG. 1, the second facet mirror 22 is arranged in an area conjugate to the entrance pupil of the projection optics unit 10. The first facet mirror 20 is arranged so as to be tilted with respect to the object plane 6. The first facet mirror 20 is arranged so as to be tilted with respect to an arrangement plane defined by the deflection mirror 19. The first facet mirror 20 is arranged with a tilt relative to an arrangement plane defined by the second facet mirror 22.

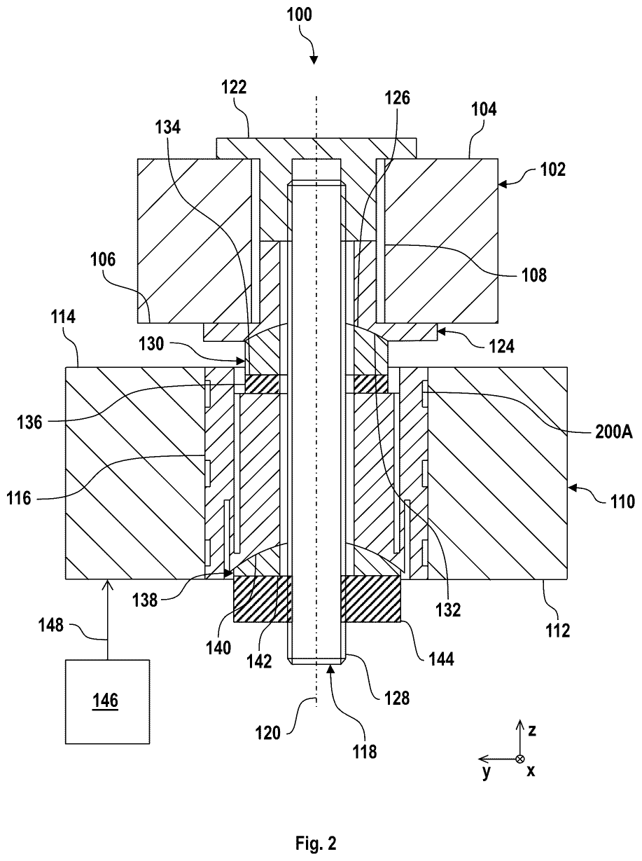

FIG. 2 shows a schematic sectional view of an embodiment of an optical system 100 for the projection exposure apparatus 1.

The optical system 100 can be part of a projection optics unit 10 as explained above. However, the optical system 100 can also be part of an illumination optics unit 4 as mentioned above. However, it is assumed below that the optical system 100 is part of a projection optics unit 4 of this type. The optical system 100 is suitable for DUV lithography. However, the optical system 100 can also be suitable for EUV lithography.

The optical system 100 has a first component 102. The first component 102 can be a sensor frame and can therefore also be referred to in this way. The first component 102 has a top side 104 and a bottom side 106 facing away from the top side 104. A perforation 108 breaks through the first component 102. The perforation 108 can be a drilled hole.

In addition to the first component 102, the optical system 100 has a second component 110. The second component 110 can be an optical element and can therefore also be referred to as such. For example, the second component 110 is a measurement target. The second component 110, for example, is made of glass ceramic.

The second component 110 has an optically effective surface 112 oriented downward in the orientation of FIG. 2. The optically effective surface 112 is a mirror surface. The optically effective surface 112 can be realized by a coating. The second component 110 has a back side 114 facing away from the optically effective surface 112. The back side 114 has no defined optical properties. The back side 114 faces the bottom side 106 of the first component 102. A perforation 116 breaks through the second component 110. The perforation 116 can be a drilled hole.

The second component 110 is attached to the first component 102 via a fastening device 118. The fastening device 118 is assigned an axis of symmetry or central axis 120, relative to which the fastening device 118 has a rotationally symmetric structure.

The fastening device 118 has a first sleeve 122 and a second sleeve 124. The first sleeve 122 abuts the top side 104 of the first component 102 and passes at least in sections through the perforation 108. For example, the first sleeve 122 is made of stainless steel.

The second sleeve 124 abuts the bottom side 106 of the first component 102 and passes at least in sections through the perforation 108. For example, the second sleeve 124 is made of an iron-nickel alloy. The second sleeve 124 has a spherical-cap-shaped contact surface 126. A “spherical cap” is here understood to mean a section of a sphere. The first sleeve 122 and the second sleeve 124 are screwed together (not shown) so that the first component 102 is clamped between the two sleeves 122, 124. For example, the first sleeve 122 is screwed into the second sleeve 124.

The fastening device 118 further has a threaded pin 128 which is screwed into the first sleeve 122. The threaded pin 128 is passed through the second sleeve 124 and thus also through the perforation 108 of the first component 102 and through the perforation 116 of the second component 110. The threaded pin 128 can be made of stainless steel.

A first spherical cap element 130 abuts the contact surface 126 of the second sleeve 124. The first spherical cap element 130 can be made of stainless steel. The threaded pin 128 is passed centrally through the first spherical cap element 130. The first spherical cap element 130 has a spherical cap-shaped first contact surface 132, with which the first spherical cap element 130 abuts the contact surface 126 of the second sleeve 124. Facing away from the first contact surface 132, the first spherical cap element has a flat second contact surface 134.

A spacer 136 abuts the second contact surface 134. The spacer 136 can be made of stainless steel. There may be multiple spacers 136 of various thicknesses. For example, coarse spacers and fine spacers may be provided. The threaded pin 128 is passed centrally through the spacer 136. With the aid of the spacer 136, the second component 110 can be positioned in the z-direction z.

The spacer 136 is placed between the first spherical cap element 130 and a decoupling bushing 200A of the fastening device 118. The decoupling bushing 200A is explained in detail below. The decoupling bushing 200A is adhesively bonded into the perforation 116 in the second component 110. Therefore, the decoupling bushing 200A can also be referred to as an adhesion bushing. The threaded pin 128 is passed centrally through the decoupling bushing 200A. The decoupling bushing 200A is made of an iron-nickel alloy, for example.

A second spherical cap element 138 abuts the decoupling bushing 200A. The second spherical cap element 138 can be made of stainless steel. The threaded pin 128 is passed centrally through the second spherical cap element 138. The second spherical cap element 138 comprises a spherical cap-shaped first contact surface 140 with which the second spherical cap element 138 abuts the decoupling bushing 200A. Facing away from the first contact surface 140, the second spherical cap element 138 has a flat second contact surface 142.

The fastening device 118 further has a nut 144 screwed onto the threaded pin 128. The nut 144 is made, for example, of stainless steel. The nut 144 abuts the second contact surface 142 of the second spherical cap element 138.

The optical system 100 comprises an interferometer 146, which interacts with the optically effective surface 112 of the second component 110 via a laser beam 148.

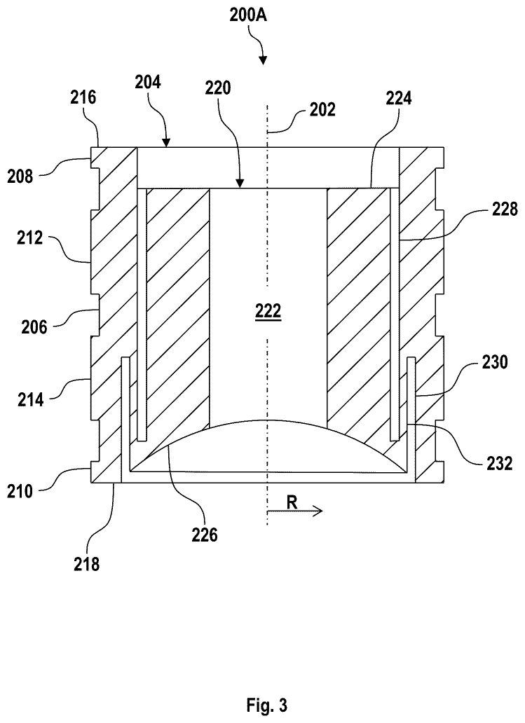

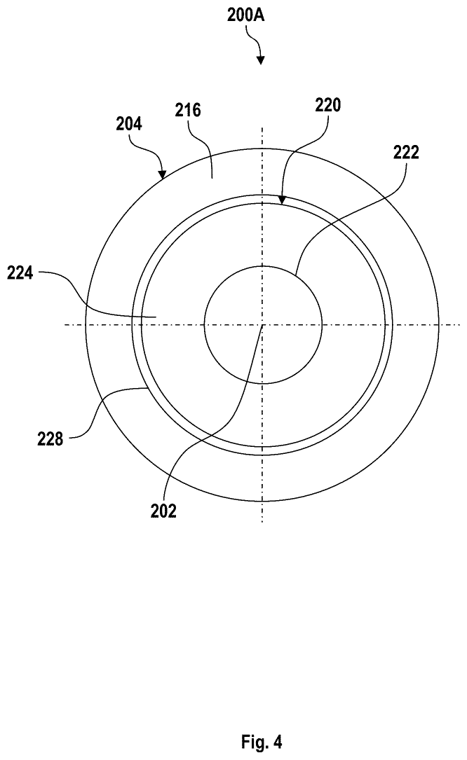

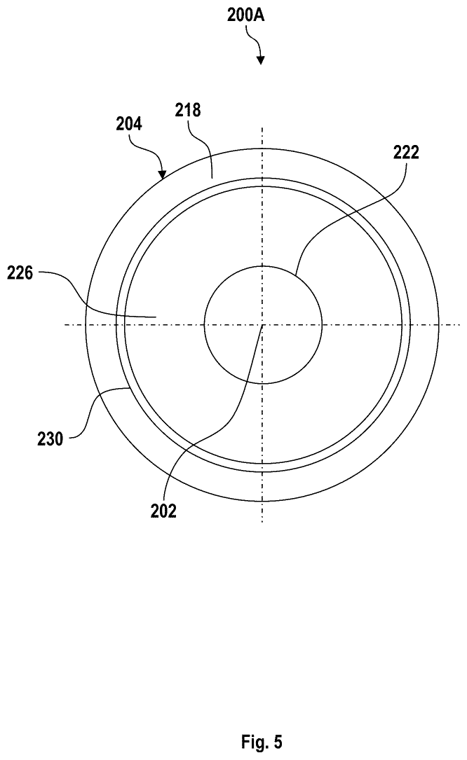

FIG. 3 shows a schematic sectional view of the decoupling bushing 200A. FIG. 4 shows a schematic plan view of the decoupling bushing 200A. FIG. 5 shows a schematic bottom view of the decoupling bushing 200A. In the following text, reference is made to FIGS. 3 to 5 at the same time.

The decoupling bushing 200A has an axis of symmetry or central axis 202, relative to which the decoupling bushing 200A has a rotationally symmetric structure. Furthermore, the decoupling bushing 200A is assigned a radial direction R. The radial direction R is oriented perpendicularly to the central axis 202 and away from the latter. The decoupling bushing 200A is a one-piece component part, for example one which is materially formed in one piece. “One-piece” or “one-part” herein means that the decoupling bushing 200A is not composed of various individual component parts, but forms a continuous component part. In the present case. “materially in one piece” means that the decoupling bushing 200A is produced from the same material throughout.

The decoupling bushing 200A has a cylindrical fastening section 204 which is connected, for example adhesively bonded, to the second component 110. The fastening section 204 is adhesively bonded into the perforation 116 in the second component 110. The fastening section 204 is rotationally symmetric in relation to the central axis 202. The fastening section 204 has a cylindrical outer surface 206.

From the outer surface 206, a first centering ring 208 and a second centering ring 210 extend, viewed along the radial direction R. Using the centering rings 208, 210, the decoupling bushing 200A is centered in the perforation 116 in the second component 110. The centering rings 208, 210 are annular and run completely around the central axis 202.

Between the two centering rings 208, 210, a first fastening ring 212 and a second fastening ring 214 are placed, which also extend, when viewed along the radial direction R, from the outer surface 206. The fastening rings 212, 214 are annular and run completely around the central axis 202. Using the fastening rings 212, 214, the decoupling bushing 200A is adhesively bonded into the perforation 116 in the second component 110. The decoupling bushing 200A is adhesively bonded radially to the second component 110 via the fastening rings 212, 214. Alternatively, however, axial adhesive bonding may also be provided. For axial adhesive bonding, a circumferential collar can be provided on the decoupling bushing 200A, which is adhesively bonded to the second component 110. The fastening section 204 has a first end face 216 and a second end face 218 facing away from the first end face 216.

Arranged within the fastening section 204, is a cylindrical connection section 220, which is rotationally symmetric to the central axis 202. The connection section 220 has a centric perforation 222 through which the threaded pin 128 is passed. The perforation 222 can be a drilled hole.

The connection section 220 has a flat first contact surface 224, against which the spacer 136 abuts. Facing away from the first contact surface 224, the connection section 220 has a spherical-cap-shaped second contact surface 226. The first contact surface 140 of the second spherical cap element 138 abuts the second contact surface 226.

Between the fastening section 204 and the connection section 220, a first undercut or a first decoupling groove 228 is provided, which separates the fastening section 204 and the connection section 220 from each other. The first decoupling groove 228 runs completely around the central axis 202. The first decoupling groove 228 is a ring groove and may therefore also be referred to as such. The first decoupling groove 228 extends from the first end face 216 in the direction of the second end face 218. However, the first decoupling groove 228 does not completely break through the decoupling bushing 200A.

A second undercut or a second decoupling groove 230, which separates the fastening section 204 and the connection section 220 from each other, is further provided between the fastening section 204 and the connection section 220. The second decoupling groove 230 runs completely around the central axis 202. The second decoupling groove 230 is a ring groove and may therefore also be referred to as such. In contrast to the first decoupling groove 228, the second decoupling groove 230 extends from the second end face 218 in the direction of the first end face 216. However, the second decoupling groove 230 does not completely break through the decoupling bushing 200A.

Viewed along the radial direction R, the first decoupling groove 228 is arranged within the second decoupling groove 230 and the second decoupling groove 230 is arranged outside the first decoupling groove 228. Viewed along the central axis 202, the decoupling grooves 228, 230 overlap each other so that the fastening section 204 and the connection section 220 are connected to each other only via a bridge 232. The bridge 232 is sleeve-shaped or tubular.

By changing a wall thickness of the bridge 232 its rigidity can be varied. In the present case, the “rigidity” should be understood to mean the resistance of a body, specifically the bridge 232, to an elastic deformation impressed thereon by an external load and conveys the relationship between the load on the body and its deformation. The rigidity is determined by the material of the body and its geometry.

The bridge 232 acts as a flexure between the fastening section 204 and the connection section 220. In the present case, a “flexure” should be understood to mean a region of a component which, by bending, allows a relative movement between two rigid body regions. In the present case, the fastening section 204 and the connection section 220 act as rigid body regions, between which the bridge 232 is provided as an elastically deformable flexure.

The functionality of the fastening device 118 will be explained hereinafter. To connect the two components 102, 110, the sleeves 122, 124 are first mounted on the perforation 108 of the first component 102. The threaded pin 128 is then screwed into the first sleeve 122.

The decoupling bushing 200A is adhesively bonded into the perforation 116 in the second component 110 using the fastening rings 212, 214. The first spherical cap element 130, the spacer 123, the decoupling bushing 200A, and the second spherical cap element 138 are threaded onto the threaded pin 128. The nut 144 is screwed onto the threaded pin 128, but is not yet tightened.

Using the spherical cap elements 130, 138, angular errors of the two components 102, 110 can now be compensated for relative to each other. In the process, the second component 110 can be tilted relative to the first component 102 around the x-direction and/or the y-direction y. The threaded pin 128 is gripped with a tool and stretched in a defined manner. Then the nut 144 is applied hand-tight at first, while the threaded pin 128 continues to be stretched. For this purpose, the aforementioned tool for stretching the threaded pin 128 is used. After the nut 144 has been applied, the tool is removed. As a result, no torque is introduced into the fastening device 118.

In the event that the decoupling bushing 200A does not have the decoupling grooves 228, 230, which reduce the rigidity of the decoupling bushing 200A in comparison with a solid bushing (not shown), it can be the case that due to unfavorable friction conditions the spherical cap elements 130, 138 do not slip into their optimal position, i.e. are not positioned optimally. Due to the resulting misalignment, a torque can be generated, which can lead to an unwanted deformation of the second component 110, for example the optically effective surface 112.

This deformation can be introduced into the second component 110 via the aforementioned solid bushing and lead to an unwanted and non-compensable deformation of the optically effective surface 112. By providing the decoupling grooves 228, 230 or the bridge 232 serving as a flexure, the torque or the deformation is absorbed in the decoupling bushing 200A itself and cannot be transferred to the second component 110. The optical system 100 thus becomes significantly more robust against friction effects, which are particularly unfavorable under EUV conditions. A dependency on the coefficients of friction and the performance of the second component 110 is therefore no longer present. Even small shape deviations of the individual component parts of the fastening device 118 can be compensated.

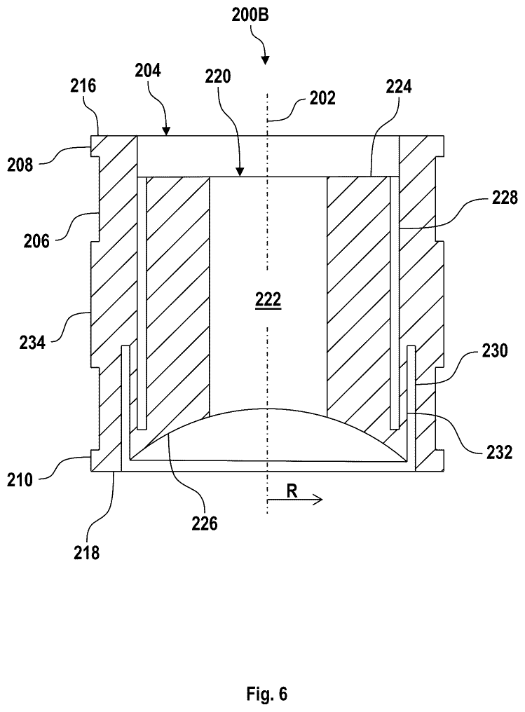

FIG. 6 shows a schematic sectional view of a further embodiment of a decoupling bushing 200B.

The decoupling bushing 200B differs from the decoupling bushing 200A only in that instead of two fastening rings 212, 214, exactly one fastening ring 234 is provided, which is placed centrally between the centering rings 208, 210 when viewed along the central axis 202. All statements regarding the decoupling bushing 200A are correspondingly applicable to the decoupling bushing 200B, and vice versa.

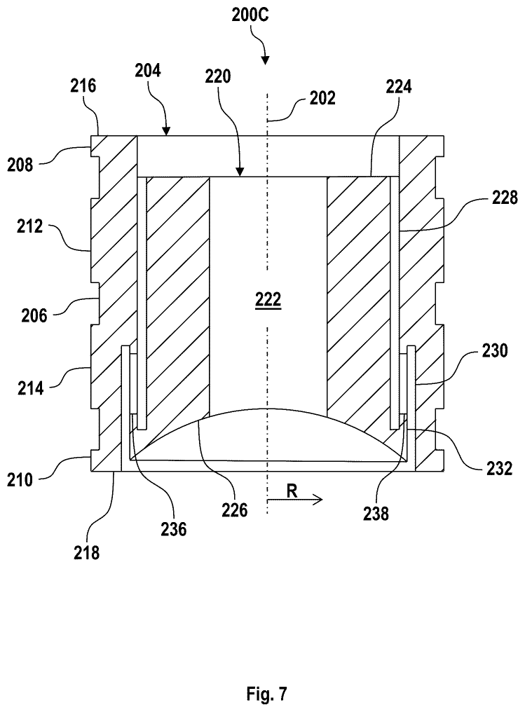

FIG. 7 shows a schematic sectional view of a further embodiment of a decoupling bushing 200C.

The decoupling bushing 200C differs from the decoupling bushing 200A only in that the bridge 232 has any number of perforations or slits 236, 238 breaking through the bridge 232. The slits 236, 238 can be arranged distributed uniformly around the central axis 202. By introducing the slits 236, 238, the rigidity of the bridge 232 can be reduced. The rigidity of the bridge 232 can thus be varied or adapted in a wide range by the size and number of slits 236, 238. All versions concerning the decoupling bushings 200A, 200B can be used correspondingly for the decoupling bushing 200C and vice versa.

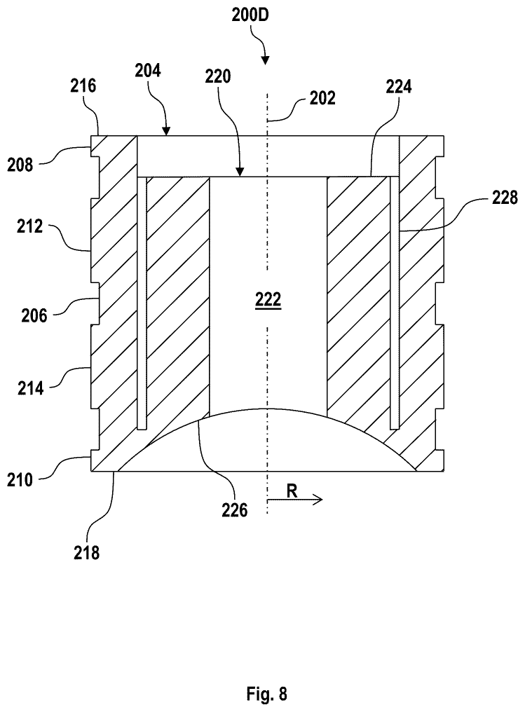

FIG. 8 shows a schematic sectional view of a further embodiment of a decoupling bushing 200D.

The decoupling bushing 200D differs from the decoupling bushing 200A only in that instead of two decoupling grooves 228, 230, only the first decoupling groove 228 is provided. In this case, the second decoupling groove 230 is dispensable. Alternatively, only the second decoupling groove 230 may be provided. In this case, the first decoupling groove 228 is dispensable. All versions concerning the decoupling bushings 200A, 200B, 200C can be applied accordingly to the decoupling bushing 200D and vice versa.

Although the present disclosure has been described on the basis of exemplary embodiments, it is modifiable in diverse ways.

### LIST OF REFERENCE SIGNS

1 Projection exposure apparatus
2 Illumination system
3 Light source
4 Illumination optics unit
5 Object field
6 Object plane
7 Reticle
8 Reticle holder
9 Reticle displacement drive
10 Projection optics unit
11 Image field
12 Image plane
13 Wafer
14 Wafer holder
15 Wafer displacement drive
16 Illumination radiation
17 Collector
18 Intermediate focal plane
19 Deflection mirror
20 First facet mirror
21 First facet
22 Second facet mirror
23 Second facet
100 Optical system
102 Component
104 Top side
106 Bottom side
108 Perforation
110 Component
112 Optically effective surface
114 Back side
116 Perforation
118 Fastening device
120 Central axis
122 Sleeve
124 Sleeve
126 Contact surface
128 Threaded pin
130 Spherical cap element
132 Contact surface
134 Contact surface
136 Spacer
138 Spherical cap element
140 Contact surface
142 Contact surface
144 Nut
146 Interferometer
148 Laser beam
200A Decoupling bushing
200B Decoupling bushing
200C Decoupling bushing
200D Decoupling bushing
202 Central axis
204 Fastening section
206 Outer surface
208 Centering ring
210 Centering ring
212 Fastening ring
214 Fastening ring
216 End face
218 End face
220 Connection section
222 Perforation
224 Contact surface
226 Contact surface
228 Decoupling groove
230 Decoupling groove
232 Bridge
234 Fastening ring
236 Slot
238 Slot
M1 Mirror
M2 Mirror
M3 Mirror
M4 Mirror
M5 Mirror
M6 Mirror
R Radial direction
X x-direction
y y-direction
Z z-direction

What is claimed is:

1. An optical system, comprising:
a first component;
a second component; and
a fastening device fastening the second component with the first component,
wherein:
the fastening device comprises a decoupling bushing configured to mechanically decouple the second component from the first component; and
the decoupling bushing comprises a decoupling groove to reduce a rigidity of the decoupling bushing.

2. The optical system of claim 1, wherein the decoupling groove is ring-shaped around a central axis of the decoupling bushing.

3. The optical system of claim 2, wherein:
The decoupling bushing comprises a first end face, a second end face, a first decoupling groove and a second decoupling groove;
the first decoupling groove extends from the first end face in a direction of the second end face; and
the second decoupling groove extends from the second end face in the direction of the first end face.

4. The optical system of claim 3, wherein, when viewed along a radial direction of the decoupling bushing, the first decoupling groove is within the second decoupling groove.

5. The optical system of claim 4, wherein, when viewed along the central axis, the first and second decoupling grooves overlap.

6. The optical system of claim 3, wherein, when viewed along the central axis, the first and second decoupling grooves overlap.

7. The optical system of claim 2, wherein, when viewed along the central axis, the first and second decoupling grooves overlap.

8. The optical system of claim 1, wherein:
the decoupling bushing comprises a connection section connected to the first component;
the decoupling bushing comprises a fastening section connected to the second component; and
the decoupling groove is between the connection section and the fastening section.

9. The optical system of claim 8, wherein the connection and fastening sections are connected to each other by only a bridge configured as a flexure.

10. The optical system of claim 9, wherein the bridge is sleeve-shaped.

11. The optical system of claim 9, wherein the bridge comprises slits breaking through the bridge.

12. The optical system of claim 8, wherein the connection section comprises a flat contact surface and a spherical-cap-shaped contact surface facing away from the flat contact surface.

13. The optical system of claim 1, wherein:
the second component comprises a perforation; and
the decoupling bushing comprises first and second centering rings configured to center and decouple the decoupling bushing in the perforation.

14. The optical system of claim 13, wherein the decoupling bushing comprises first and second fastening rings configured to attach the decoupling bushing to the perforation, and wherein the first and second fastening rings are arranged between the first and second centering rings.

15. The optical system of claim 13, wherein the decoupling bushing has exactly one fastening ring configured to attach the decoupling bushing to the perforation, and the fastening ring is between the first and second centering rings.

16. The optical system of claim 1, wherein the decoupling bushing is a one-piece component part.

17. The optical system of claim 16, wherein the decoupling bushing is materially in one piece.

18. The optical system of claim 16, wherein the decoupling groove is ring-shaped around a central axis of the decoupling bushing.

19. The optical system of claim 1, wherein:
the decoupling bushing comprises a connection section connected to the first component;
the decoupling bushing comprises a fastening section connected to the second component; and
the decoupling groove is between the connection section and the fastening section.

20. An apparatus, comprising:
an optical system according to claim 1,
wherein the apparatus is a projection exposure apparatus.
